(19) United States
(12) Patent Application Publication
(10) Pub. No.: US 2021/0408382 A1
(43) Pub. Date: Dec. 30, 2021

(54) PEROVSKITE LIGHT-EMITTING DIODE AND PREPARING METHOD THEREOF

(71) Applicant: Shenzhen China Star Optoelectronics Semiconductor Display Technology Co., Ltd., Shenzhen (CN)

(72) Inventors: Yongwei WU, Shenzhen (CN); Chiayu LEE, Shenzhen (CN); Chunche HSU, Shenzhen (CN); Bo HE, Shenzhen (CN); Pei JIANG, Shenzhen (CN); Yongming YIN, Shenzhen (CN); Miao DUAN, Shenzhen (CN)

(73) Assignee: Shenzhen China Star Optoelectronics Semiconductor Display Technology Co., Ltd., Shenzhen (CN)

(21) Appl. No.: 16/620,516

(22) PCT Filed: Nov. 5, 2019
(86) PCT No.: PCT/CN2019/115817

§ 371 Date: Dec. 8, 2019

(30) Foreign Application Priority Data
Sep. 9, 2019 (CN) 201910845968.7

(51) Int. Cl. H01L 51/00; H01L 51/50; H01L 51/56

(52) U.S. Cl. CPC H01L 51/0007; H01L 51/5056; H01L 51/56; H01L 51/5072; H01L 51/5012

(57) ABSTRACT

A perovskite organic light-emitting diode and a preparing method thereof are provided. The perovskite organic light-emitting diode comprises an anode layer, a hole transport layer, a light-emitting layer, an electron transport layer and a cathode layer. The hole transport layer, the light-emitting layer and the electron transport layer are prepared by solution processing. Every film layer is prepared by solution spin coating and dried, thereby the whole preparing process is simple, material utilization rate is high and luminous performance of the device is excellent.

### FIELD OF INVENTION

The present disclosure relates to the field of display technologies, and more particularly to a perovskite light-emitting diode and a preparing method thereof.

### BACKGROUND OF INVENTION

Organic light-emitting diodes (OLEDs) display devices are self-illuminating, have fast response times, are light and thin compared to liquid crystal display devices, and are widely used in many fields.

With development of technologies, the types of light-emitting diodes are also expanding, and perovskite material is introduced into organic light-emitting diodes for improving luminous efficiency of devices. Perovskite material has advantages of high efficiency, high brightness, and high color purity, so it can improve the performance of organic light-emitting diodes when introducing into organic light-emitting diodes. A multilayer device structure is usually used in perovskite light-emitting diodes by disposing hole and electron transport matching layers between a perovskite light-emitting layer, a cathode and an anode. In current manufacturing process of perovskite organic light-emitting diodes devices, vacuum evaporation is usually used. This manufacturing process has high requirement for equipment, the current manufacturing processes is complex and difficult to operate and it cost a lot of materials during the manufacturing process meanwhile, thereby causing problems of long production cycle, low product yield, and high production costs of perovskite organic light-emitting diodes. Therefore, it is necessary to propose a solution to the problems in the prior art.

In summary, the current manufacturing process of perovskite organic light-emitting diodes has high requirement for equipment, is complex and difficult to operate, and it cost a lot of materials during the manufacturing process meanwhile, thereby causing problems of long production cycle, low product yield, and high production costs of perovskite organic light-emitting diodes.

### SUMMARY OF INVENTION

To solve above problems, an object of the present disclosure is to provide a perovskite organic light-emitting diode and a preparing method thereof to solve the problems of complex production process, a low device qualification rate and high costs in current preparing process of perovskite organic light-emitting diodes.

To achieve the above object, an embodiment of the present disclosure provides following technical solutions:

An embodiment of the present disclosure provides a preparing method of a perovskite organic light-emitting diode. The method comprises following steps:

S100: preparing an anode layer on a substrate;

S101: preparing a hole transport layer: coating a polymer aqueous solution on the anode layer and drying after coating to obtain the hole transport layer;

S102: preparing a light-emitting layer: coating a perovskite precursor solution on the hole transport layer and drying after coating to obtain the light-emitting layer;

S103: preparing an electron transport layer: coating a mixed solution for the electron transport layer on the light-emitting layer and drying after coating to obtain the electron transport layer;

S104: preparing a cathode layer: after finishing the above steps, preparing a cathode layer on the electron transport layer;

wherein in the step S101, the coating is a spin coating process, and a rate of spin coating ranges from 2500 rpm to 4000 rpm;

wherein in the step S102, the coating is a spin coating process, and a rate of spin coating ranges from 500 rpm to 5000 rpm.

In an embodiment of the present disclosure, wherein in the step S102, solutes in the perovskite precursor solution comprise MABr and PbBr₂.

In an embodiment of the present disclosure, wherein in the step S101, time for the spin coating process ranges from 40 seconds to 80 seconds.

In an embodiment of the present disclosure, wherein after the spin coating process, dry by an annealing process at a temperature of 120° C. to 160° C. for 15 minutes to 30 minutes.

In an embodiment of the present disclosure, wherein in the step S102, time for the spin coating process ranges from 50 seconds to 120 seconds.

In an embodiment of the present disclosure, wherein after the spin coating process, dry by an annealing process at a temperature of 80° C. to 120° C. for 10 minutes to 60 minutes.

In an embodiment of the present disclosure, wherein in the step S103, the coating is a spin coating process, a rate of spin coating ranges from 2500 rpm to 4000 rpm, and time for the spin coating process ranges from 30 seconds to 90 seconds.

In an embodiment of the present disclosure, wherein after the spin coating process, dry by an annealing process at a temperature of 60° C. to 100° C. for 15 minutes to 30 minutes.

In an embodiment of the present disclosure, wherein the mixed solution for the electron transport layer comprises a TPBi solution, a concentration of the TPBi solution ranges from 0.02 mol/L to 0.08 mol/L.

An embodiment of the present disclosure provides a preparing method of a perovskite organic light-emitting diode. The method comprises following steps:

S100: preparing an anode layer on a substrate;

S101: preparing a hole transport layer: coating a polymer aqueous solution on the anode layer and drying after coating to obtain the hole transport layer;

S102: preparing a light-emitting layer: coating a perovskite precursor solution on the hole transport layer and drying after coating to obtain the light-emitting layer;

S103: preparing an electron transport layer: coating a mixed solution for electron transport layer on the light-emitting layer and drying after coating to obtain the electron transport layer;

S104: preparing a cathode layer, after finishing the above steps, preparing a cathode layer on the electron transport layer.

In an embodiment of the present disclosure, wherein in the step S102, solutes in the perovskite precursor solution comprise MABr and PbBr₂.

In an embodiment of the present disclosure, wherein in the step S101, the coating is a spin coating process, a rate of spin coating ranges from 2500 rpm to 4000 rpm, and time for the spin coating process ranges from 40 seconds to 80 seconds.

In an embodiment of the present disclosure, wherein after the spin coating process, dry by an annealing process at a temperature of 120° C. to 160° C. for 15 minutes to 30 minutes.

In an embodiment of the present disclosure, wherein in the step S102, the coating is a spin coating process, a rate of spin coating ranges from 2500 rpm to 5000 rpm, and time for the spin coating process ranges from 50 seconds to 120 seconds.

In an embodiment of the present disclosure, wherein after the spin coating process, dry by an annealing process at a temperature of 80° C. to 120° C. for 10 minutes to 60 minutes.

In an embodiment of the present disclosure, wherein in the step S103, the coating is a spin coating process, a rate of spin coating ranges from 2500 rpm to 4000 rpm, and time for the spin coating process ranges from 30 seconds to 90 seconds.

In an embodiment of the present disclosure, wherein after the spin coating process, dry by an annealing process at a temperature of 60° C. to 100° C. for 15 minutes to 30 minutes.

In an embodiment of the present disclosure, wherein the mixed solution for the electron transport layer comprises a TPBi solution, a concentration of the TPBi solution ranges from 0.02 mol/L to 0.08 mol/L.

An embodiment of the present disclosure provides a perovskite organic light-emitting diode. The perovskite organic light-emitting diode comprises an anode layer, a hole transport layer, a light-emitting layer, an electron transport layer and a cathode layer disposed in sequence from bottom to top; wherein the hole transport layer, the light-emitting layer and the electron transport layer are prepared by solution processing.

In summary, the beneficial effect of the embodiments of the present disclosure is: providing a perovskite organic light-emitting diode and a preparing method thereof by a solution spin-coating process to prepare a hole transport layer, a light-emitting layer and an electron transport layer of the organic light-emitting diode and performing a corresponding annealing process after the solution spin-coating to obtain the film layers. The hole transport layer, the light-emitting layer and the electron transport layer are prepared by solution processing. This process is simple and equipment required for production is simple, while material utilization rate is high and product performance is better.

### DESCRIPTION OF DRAWINGS

FIG. 1 is a schematic structural diagram of a perovskite organic light-emitting diode according to an embodiment of the present disclosure.

FIG. 2 is a preparing process flowchart of a perovskite organic light-emitting diode according to an embodiment of the present disclosure.

FIG. 3 is a schematic preparing diagram of a hole transport layer according to an embodiment of the present disclosure.

FIG. 4 is a schematic preparing diagram of a light-emitting layer according to an embodiment of the present disclosure.

### DETAILED DESCRIPTION OF PREFERRED EMBODIMENTS

The accompanying figures to be used in the description of embodiments of the present disclosure will be described in brief to more clearly illustrate the technical solutions of the embodiments.

In an embodiment of the present disclosure, as shown in FIG. 1, FIG. 1 is a schematic structural diagram of a perovskite organic light-emitting diode according to an embodiment of the present disclosure. The perovskite organic light-emitting diode in an embodiment of the present disclosure comprises an anode layer 100, a hole transport layer 101, a light-emitting layer 102, an electron transport layer 103 and a cathode layer 104 disposed in sequence from bottom to top. Wherein the anode layer 100 comprises an indium tin oxide (ITO) film, the cathode layer 104 comprises an Al layer and a LiF layer, preferably, the thickness of the LiF layer is 1 nm, and the thickness of the Al layer ranges from 90 nm to 120 nm.

Vacuum evaporation is used to prepare every film layer in conventional perovskite organic light-emitting diode. It has high requirement for equipment and high production costs. In the embodiment, the film layers of the perovskite organic light-emitting diode are prepared by solution processing. Specifically, the hole transport layer 101, the light-emitting layer 102 and the electron transport layer 103 are prepared by solution processing, thereby the whole preparing process is simpler.

In the preparing process, the solution is coated by a spin coating process, and dried after the coating to obtain the needed film layer.

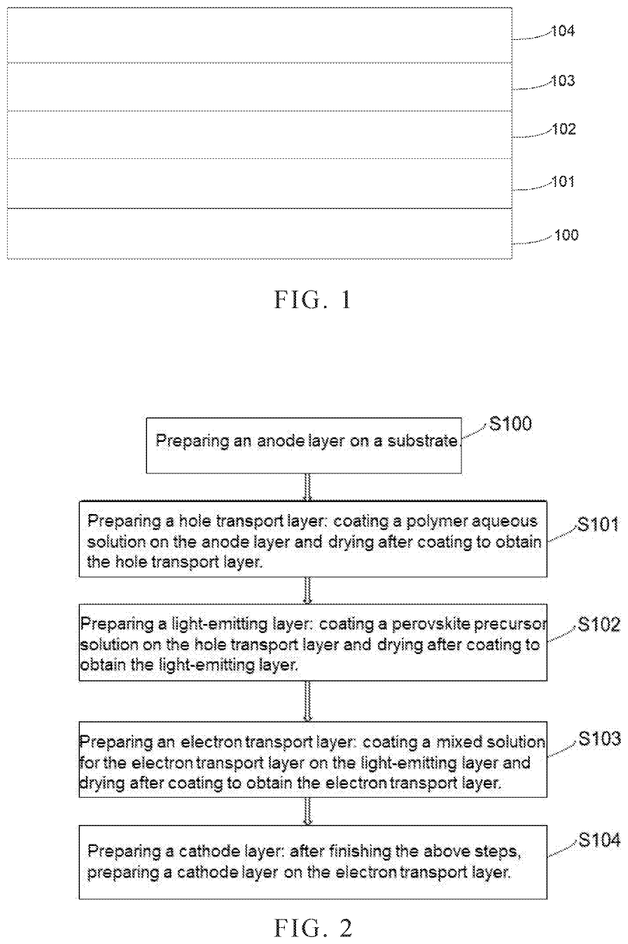

Specifically, as shown in FIG. 2, FIG. 2 is a preparing process flowchart of a perovskite organic light-emitting diode according to an embodiment of the present disclosure. The preparing method of the perovskite organic light-emitting diode in an embodiment of the present disclosure comprises following steps:

S100: preparing an anode layer on a substrate.

First, select a substrate, clean and dry the substrate. After the preparation, an anode layer is disposed on the substrate. The anode layer is deposited by spin coating. The anode layer in the embodiment of the present disclosure comprises ITO film layer.

S101: preparing a hole transport layer: coating a polymer aqueous solution on the anode layer and drying after coating to obtain the hole transport layer.

After preparation of the anode layer, prepare a hole transport layer of the perovskite organic light-emitting diode. As shown in FIG. 3, FIG. 3 is a schematic preparing diagram of a hole transport layer according to an embodiment of the present disclosure.

In the preparation of the hole transport layer, a polymer aqueous solution 301 in a solution storage device 302 is coated on the anode layer 300 by spin coating. The polymer aqueous solution comprises poly (3,4-ethylenedioxythiophene)-poly (styrene sulfonate) (PEDOT: PSS).

Wherein the rate of spin coating ranges from 2500 rpm to 4000 rpm, and time for the spin coating ranges from 40 seconds to 80 seconds. Perform an annealing process on the device at a temperature of 120° C. to 160° C. for 15 minutes to 30 minutes when the solution is coated uniformly on the anode layer to obtain the hole transport layer of the perovskite organic light-emitting diode.

S102: preparing a light-emitting layer: coating a perovskite precursor solution on the hole transport layer and drying after coating to obtain the light-emitting layer.

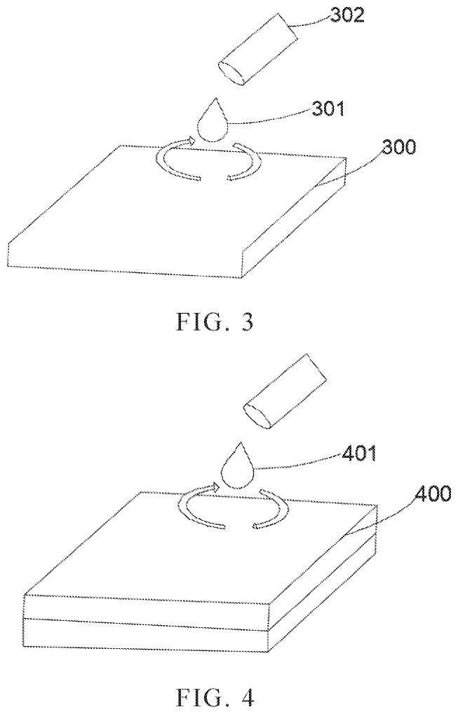

Preparation of the light-emitting layer of the perovskite light-emitting diode, specifically, is as shown in FIG. 4, FIG. 4 is a schematic preparing diagram of a light-emitting layer according to an embodiment of the present disclosure. The perovskite precursor solution 401 is coated on the hole transport layer 400 by spin coating. Perform an annealing process after the spin coating.

During the spin coating, the rate of the spin coating ranges from 2500 rpm to 5000 rpm, and time for the spin coating ranges from 50 seconds to 120 seconds. During the annealing process, it is at a temperature of 80° C. to 120° C. for 10 minutes to 60 minutes.

Wherein in preparation of the perovskite precursor solution in an embodiment of the present disclosure, solutes in the perovskite precursor solution comprise MABr and PbBr₂. Preferably, in an embodiment of the present disclosure, MABr and PbBr₂ are mixed to obtain MAPbBr₃ perovskite. When preparing the perovskite precursor solution, molar ratio of MABr to PbBr₂ is 1:1 or 1.2:1. Both of mixing ratios can obtain MAPbBr₃ perovskite with different luminous performances, and the mixing ratio is determined in accordance of specific products. In an embodiment of the present disclosure, the light-emitting layer contains perovskite material, and the perovskite material has advantages of high efficiency, high brightness, and high color purity. Therefore, the performance of organic light-emitting diodes prepared thereof is better.

S103: preparing an electron transport layer: coating a mixed solution for the electron transport layer on the light-emitting layer and drying after coating to obtain the electron transport layer.

In preparation of the electron transport layer, the mixed solution for the electron transport layer is coated on the light-emitting layer and an annealing process was performed after spin coating uniformly. Specifically, the rate of the spin coating ranges from 2500 rpm to 4000 rpm, time for the spin coating ranges from 30 seconds to 90 seconds, and it is annealed at a temperature of 60° C. to 100° C. for 15 minutes to 30 minutes.

Preferably, the mixed solution for the electron transport layer comprises 1, 3, 5-tris (1-phenyl-1H-benzimidazol-2-yl) benzene (TPBi). TPBi has deeper electron energy level and good carrier (electron) mobility, it has excellent luminous performance when illuminating. When preparing TPBi solution, the concentration of the solution ranges from 0.02 mol/L to 0.08 mol/L. A solvent for TPBi solution is selected from toluene, chlorobenzene, chloroform, isopropanol or other solvents.

In an embodiment of the present disclosure, the TPBi electron transport layer is prepared by solution spin coating process, the preparation is simple and material utilization rate is high.

S104: preparing a cathode layer: after finishing the above steps, preparing a cathode layer on the electron transport layer.

After step S103, prepare the cathode layer. Wherein the cathode layer is prepared by vacuum evaporation. The cathode layer comprises an Al layer and a LiF layer, preferably, the thickness of the Al layer ranges from 90 nm to 120 nm and the thickness of the LiF layer is 1 nm. Thicknesses of other film layers are determined in accordance of specific products.

Last, the perovskite organic light-emitting diode in an embodiment of the present disclosure can be obtained.

Above detailed description is to illustrate a perovskite organic light-emitting diode and a preparing method thereof in an embodiment of the present disclosure. The specific embodiments described above with reference to the attached drawings are all exemplary and are intended to illustrate and interpret the technical solutions and the core ideas of the present disclosure. It is understood that many changes and modifications to the described embodiment can be carried out without departing from the scope and the spirit of the disclosure that is intended to be limited only by the appended claims.

What is claimed is:

1. A preparing method of a perovskite organic light-emitting diode, comprising following steps:
S100: preparing an anode layer on a substrate;
S101: preparing a hole transport layer: coating a polymer aqueous solution on the anode layer and drying after coating to obtain the hole transport layer;
S102: preparing a light-emitting layer: coating a perovskite precursor solution on the hole transport layer and drying after coating to obtain the light-emitting layer;
S103: preparing an electron transport layer: coating a mixed solution for the electron transport layer on the light-emitting layer and drying after coating to obtain the electron transport layer;
S104: preparing a cathode layer: after finishing the above steps, preparing a cathode layer on the electron transport layer;
wherein in the step S101, the coating is a spin coating process, and a rate of spin coating ranges from 2500 rpm to 4000 rpm;
wherein in the step S102, the coating is a spin coating process, and a rate of spin coating ranges from 500 rpm to 5000 rpm.

2. The preparing method of the perovskite organic light-emitting diode according to claim 1, wherein in the step S102, solutes in the perovskite precursor solution comprise MABr and PbBr₂.

3. The preparing method of the perovskite organic light-emitting diode according to claim 1, wherein in the step S101, time for the spin coating process ranges from 40 seconds to 80 seconds.

4. The preparing method of the perovskite organic light-emitting diode according to claim 3, wherein after the spin coating process, dry by an annealing process at a temperature of 120° C. to 160° C. for 15 minutes to 30 minutes.

5. The preparing method of the perovskite organic light-emitting diode according to claim 1, wherein in the step S102, time for the spin coating process ranges from 50 seconds to 120 seconds.

6. The preparing method of the perovskite organic light-emitting diode according to claim 5, wherein after the spin coating process, dry by an annealing process at a temperature of 80° C. to 120° C. for 10 minutes to 60 minutes.

7. The preparing method of the perovskite organic light-emitting diode according to claim 1, wherein in the step S103, the coating is a spin coating process, a rate of spin coating ranges from 2500 rpm to 4000 rpm, and time for the spin coating process ranges from 30 seconds to 90 seconds.

8. The preparing method of the perovskite organic light-emitting diode according to claim 7, wherein after the spin coating process, dry by an annealing process at a temperature of 60° C. to 100° C. for 15 minutes to 30 minutes.

9. The preparing method of the perovskite organic light-emitting diode according to claim 1, wherein the mixed solution for the electron transport layer comprises a TPBi solution, a concentration of the TPBi solution ranges from 0.02 mol/L to 0.08 mol/L.

10. A preparing method of a perovskite organic light-emitting diode, comprising following steps:
S100: preparing an anode layer on a substrate;
S101: preparing a hole transport layer: coating a polymer aqueous solution on the anode layer and drying after coating to obtain the hole transport layer;
S102: preparing a light-emitting layer: coating a perovskite precursor solution on the hole transport layer and drying after coating to obtain the light-emitting layer;
S103: preparing an electron transport layer: coating a mixed solution for electron transport layer on the light-emitting layer and drying after coating to obtain the electron transport layer;
S104: preparing a cathode layer, after finishing the above steps, preparing a cathode layer on the electron transport layer.

11. The preparing method of the perovskite organic light-emitting diode according to claim 10, wherein in the step S102, solutes in the perovskite precursor solution comprise MABr and PbBr₂.

12. The preparing method of the perovskite organic light-emitting diode according to claim 10, wherein in the step S101, the coating is a spin coating process, a rate of spin coating ranges from 2500 rpm to 4000 rpm, and time for the spin coating process ranges from 40 seconds to 80 seconds.

13. The preparing method of the perovskite organic light-emitting diode according to claim 12, wherein after the spin coating process, dry by an annealing process at a temperature of 120° C. to 160° C. for 15 minutes to 30 minutes.

14. The preparing method of the perovskite organic light-emitting diode according to claim 10, wherein in the step S102, the coating is a spin coating process, a rate of spin coating ranges from 2500 rpm to 5000 rpm, and time for the spin coating process ranges from 50 seconds to 120 seconds.

15. The preparing method of the perovskite organic light-emitting diode according to claim 14, wherein after the spin coating process, dry by an annealing process at a temperature of 80° C. to 120° C. for 10 minutes to 60 minutes.

16. The preparing method of the perovskite organic light-emitting diode according to claim 10, wherein in the step S103, the coating is a spin coating process, a rate of spin coating ranges from 2500 rpm to 4000 rpm, and time for the spin coating process ranges from 30 seconds to 90 seconds.

17. The preparing method of the perovskite organic light-emitting diode according to claim 16, wherein after the spin coating process, dry by an annealing process at a temperature of 60° C. to 100° C. for 15 minutes to 30 minutes.

18. The preparing method of the perovskite organic light-emitting diode according to claim 10, wherein the mixed solution for the electron transport layer comprises a TPBi solution, a concentration of the TPBi solution ranges from 0.02 mol/L to 0.08 mol/L.

19. A perovskite organic light-emitting diode, comprising an anode layer, a hole transport layer, a light-emitting layer, an electron transport layer and a cathode layer disposed in sequence from bottom to top; wherein
the hole transport layer, the light-emitting layer and the electron transport layer are prepared by solution processing.
